(19) United States
(12) Patent Application Publication
(10) Pub. No.: US 2023/0357948 A1
(43) Pub. Date: Nov. 9, 2023

(54) DEVICE AND METHOD FOR MANUFACTURING A CRYSTALLINE CONVERSION LAYER FROM A SOLUTION

(71) Applicants: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR)

(72) Inventors: Jean-Marie VERILHAC, Grenoble (FR); Eric GROS D'AILLON, Grenoble (FR); Alain IBANEZ, Paris (FR); Julien ZACCARO, Paris (FR)

(73) Assignees: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR)

(21) Appl. No.: 18/027,686

(22) PCT Filed: Sep. 22, 2021
(86) PCT No.: PCT/FR2021/051630

§ 371 Date: Mar. 22, 2023

(30) Foreign Application Priority Data
Sep. 22, 2020 (FR) FR2009597

(51) Int. Cl. C30B 7/08; C30B 7/00; C30B 19/10

(52) U.S. Cl. CPC C30B 7/08; C30B 7/005; C30B 19/10; C30B 29/54

(57) ABSTRACT

A device for fabricating a crystalline conversion layer from a growth solution, has a first wall and a substrate defining between them a crystalline growth cavity; a device for inlet/outlet of the solution controlling, over time, at least the supply or extraction of the growth solution to and from the crystalline growth cavity; a heating device creating a temperature profile in the crystalline growth cavity, the substrate or the first wall; the temperature profile controlling a free formation of the crystalline conversion layer over a thickness of greater than 1 micrometer, in a direction mainly transverse to forming face; the whole of the thickness of the crystalline conversion layer being obtained by the free formation of the crystalline conversion layer.

### TECHNICAL FIELD

The present invention concerns a device for manufacturing a crystalline conversion layer by liquid process.

The invention also relates to a method for manufacturing a crystalline conversion layer implementing such a device.

### PRIOR ART

In the field of detectors of X, gamma or even charged or uncharged particle radiation, notably in the field of medical or nuclear imaging, it is important to detect as accurately as possible the quantity of emitted, received or transmitted radiation, such as typically that received by the patient or that passing through the patient. It is thus necessary to have a crystalline thick layer, that is to say greater than 1 micrometer, of conversion crystal to absorb the maximum of radiation. Depending on the target applications, it is also necessary for the crystalline conversion layer to have a surface of several square millimeters to several tens of square centimeters.

In this context, it is known to make deposits in liquid form, for example by spin centrifugation or else by methods called “slot-die” or even “doctor blade”. But if these methods are adapted to obtain thin layers having submicrometer thicknesses, they do not allow obtaining thick layers having thicknesses greater than several tens of micrometers.

A known solution to obtain a crystalline conversion thick layer consists in using a supersaturated solution between two plates of a reactor in order to obtain the crystal growth constrained between these two plates to obtain a crystalline conversion layer. This technique is called “space-limited inverse temperature crystallization”.

Further, a problem with this solution is that the temperature and distribution of the supersaturated solution are not accurately mastered, which results in a growth including structural defects. In addition, in this case, the thickness of the layer is set by the distance between the plates. This lack of control is all the more limiting as this approach promotes the growth in the plane of the layer to be produced. Thus, obtaining large surface layers requires growths over tens of square centimeters which, without control of the distribution and temperature of the solution is incompatible with the development of layers of the quality necessary for the detection of the ionizing radiation.

### DISCLOSURE OF THE INVENTION

The present invention aims to address all or part of the problems presented above.

Notably, an aim is to provide a solution that meets all or part of the following objectives:
to obtain a thick layer, of satisfactory quality, of conversion crystals directly in an optoelectronic device;
to obtain a distribution of controlled solution and temperature;
to obtain a thick layer, of satisfactory quality, of conversion crystals over a large surface preferably greater than a few square centimeters and even more preferably greater than about ten square centimeters.

This object may be achieved by means of a manufacturing device allowing manufacturing a crystalline conversion layer from a crystalline conversion layer growth solution, the manufacturing device comprising:
a first wall and a substrate defining therebetween a crystalline growth cavity;
at least one inlet/outlet device of the growth solution controlling, over time, at least one function selected from the group comprising the supply and extraction of the growth solution respectively to and from the crystalline growth cavity;
a temperature setting device creating a temperature profile in at least one element selected from the group comprising the crystalline growth cavity, the substrate and the first wall;
   the temperature profile controlling a free formation of the crystalline conversion layer over a thickness greater than 1 micrometer, from all or part of a forming face of the substrate facing the interior of the crystalline growth cavity, in a direction mainly transverse to said forming face;
   the entire thickness of the crystalline conversion layer being obtained by the free formation of the crystalline conversion layer.

Some preferred but non-limiting aspects are as follows.

In one implementation of the device, the first wall is sealingly fastened to the substrate so that the growth solution, introduced into the crystalline growth cavity by said at least one inlet/outlet device, is extracted from the crystalline growth cavity only by at least one element selected from the group comprising said at least one inlet/outlet device and a spontaneous flow evacuation arranged in the first wall or in a portion of the substrate located at the growth cavity.

In one implementation of the device, the temperature setting device comprises elements allowing modifying the temperature profile over time.

In one implementation of the device, the temperature setting device comprises elements allowing configuring the temperature profile in at least one element selected from the group comprising the crystalline growth cavity, the substrate and the first wall.

In one implementation of the device, the temperature profile created by the temperature setting device comprises at least one temperature lower than a temperature of the substrate.

In one implementation of the device, the temperature profile created by the temperature setting device comprises at least one temperature higher than a temperature of the substrate.

In one implementation of the device, all or part of the temperature setting device is arranged in at least one element selected from the group comprising the first wall, the conversion crystal liquid precursor inlet/outlet device and a second wall formed at an outer face of the substrate opposite the forming face.

In one implementation of the device, the temperature setting device comprises a plurality of control areas, each control area having an area temperature that can be modified by the temperature setting device, independently from one control area to another control area.

In one implementation, the manufacturing device comprises a plurality of separate inlet/outlet devices of the conversion crystal growth solution arranged on either side of the substrate, parallel to the forming face.

In one implementation of the device, at least one conversion crystal liquid precursor inlet/outlet device is arranged facing the forming face.

In one implementation of the device, all or part of the forming face comprises a seed layer of the conversion crystal.

In one implementation of the device, at least one part of the substrate is formed by at least one pixel;

and the seed layer comprises a plurality of percolating or non-percolating crystalline grains; and, at said at least one pixel, the seed layer includes at least one crystalline grain of the plurality of crystalline grains.

In one implementation of the device, the seed layer offers a main crystallographic orientation along an axis {n00} n being an integer comprised between 1 and 4 inclusive.

In one implementation of the device, the seed layer offers a main crystallographic orientation along an axis of the group comprising an axis {110} and an axis {111}.

In one implementation of the device, the temperature profile created by the temperature setting device is configured to obtain the formation of the crystalline conversion layer only on a limited part of the forming face of the substrate without contact with the first wall, the remaining part of the forming face remaining devoid of conversion crystal.

In one implementation of the device, at least one inlet/outlet device of the growth solution passes through at least one element selected from the group comprising the first wall and the substrate.

In one implementation of the device, the crystalline conversion layer to be formed is a perovskite of a type from the group comprising ABX₃, A′₂C¹⁺D³⁺X₆, A₂B⁴⁺X₆ or A₃B₂³⁺X₉; A, A′, C, D being cations and X being a halogen anion.

In one implementation of the device, the crystalline conversion layer to be formed is an organic-inorganic hybrid perovskite of formula respecting the electronic neutrality A⁽¹⁾_{1-(y2+ . . . +yn)}A⁽²⁾_{y2 . . .} A⁽ⁿ⁾_{yn}B⁽¹⁾_{1-(z2+ . . . +zm)}B⁽²⁾_{z2 . . .} B^{(m)}_{zm}X⁽¹⁾_{3-(x2+ . . . +xp)}X⁽²⁾_{x2 . . .} X^{(p)}ₓₚ where A⁽ⁿ⁾ and B^{(m)} where A⁽ⁿ⁾ and B^{(m)} correspond to cations and X⁽ⁿ⁾ corresponds to a halogen anion.

In one implementation of the device, the thickness of the crystalline conversion layer to be manufactured is greater than or equal to 100 micrometers.

The invention also relates to a method for manufacturing a crystalline conversion layer from a crystalline conversion layer growth solution on a substrate, the method being implemented in such a manufacturing device, the method comprising the following steps:
a) time-dependent control of at least one function selected from the group comprising the supply and extraction of the growth solution by an inlet/outlet device of a growth solution of the manufacturing device to and from a crystalline growth cavity defined between a first wall of the manufacturing device and the substrate;
b) creation of a temperature profile by a temperature setting device in at least one element selected from the group comprising the crystalline growth cavity, the substrate, and the first wall;
c) configuration of the temperature profile to control a free formation of the crystalline conversion layer in a thickness greater than 1 micrometer, from all or part of a forming face of the substrate facing the interior of the crystalline growth cavity, in a direction mainly transverse to said forming face, the entire thickness of the crystalline conversion layer being obtained by the free formation of the crystalline conversion layer.

In one implementation of the method, in step c), the configuration of the temperature profile is modified over time.

In one implementation of the method, in step c), the temperature profile is formed in at least one element selected from the group comprising the crystalline growth cavity, the substrate and the first wall.

In one implementation of the method, in step c), the temperature profile is configured to obtain the formation of the crystalline conversion layer only on a limited part of the forming face of the substrate without contact with the first wall, the remaining part of the forming face being devoid of conversion crystal.

In one implementation of the method, in step a), several growth solutions of different nature are fed into the crystalline growth cavity by the inlet/outlet device sequentially.

In one implementation of the method, the manufacturing device comprises a plurality of inlet/outlet devices and wherein, in step a), several growth solutions of different nature are fed, into the crystalline growth cavity, each by a different one of the inlet/outlet devices, at the same time or sequentially.

### BRIEF DESCRIPTION OF THE DRAWINGS

Other aspects, aims, advantages and features of the invention will better appear on reading the following detailed description of preferred embodiments thereof, given by way of non-limiting example, and made with reference to the appended drawings in which:

FIG. 1 illustrates a sectional view of an example of a manufacturing device according to the invention in which an inlet/outlet device is arranged in the first wall and in which the first wall is sealingly fastened to the substrate by a joint.

FIG. 2 illustrates a sectional view of an example of a manufacturing device according to the invention in which an inlet/outlet device is arranged in the first wall facing the forming face and two inlet/outlet devices are arranged on either side of the substrate parallel to the forming face.

FIG. 3 illustrates a sectional view of an example of a manufacturing device according to the invention in which two inlet/outlet devices are disposed on either side of the substrate parallel to the forming face and in which a crystalline conversion layer is being formed.

FIG. 4 illustrates a sectional view of an example of a manufacturing device according to the invention in which the temperature setting device is arranged along a surface smaller than that of the substrate.

FIG. 5 illustrates a sectional view of an example of a manufacturing device according to the invention in which the temperature setting device comprises several control areas.

FIG. 6 illustrates a sectional view of an example of a manufacturing device according to the invention in which the forming face comprises all or part of a seed layer of the crystalline conversion layer.

FIG. 7 illustrates a transverse view of an example of a manufacturing device according to the invention in which a temperature profile is highlighted between the first wall and the substrate.

FIG. 8 illustrates a sectional view of an example of a manufacturing device according to the invention in which a temperature profile is highlighted between the first wall and the substrate.

FIG. 9 illustrates a perspective view of an example of a manufacturing device according to the invention in which two inlet/outlet devices are disposed on either side of the substrate parallel to the forming face.

FIG. 10 illustrates a perspective view of an example of a manufacturing device according to the invention in which four inlet/outlet devices are disposed on either side of the substrate parallel to the forming face.

FIG. 11 illustrates a perspective view of an example of a manufacturing device according to the invention in which four inlet/outlet devices are disposed on either side of the substrate parallel to the forming face and in which two inlet/outlet devices are arranged facing the forming face and through the first wall.

FIG. 12 illustrates a flowchart of an example of a manufacturing method according to another aspect of the invention.

FIG. 13 illustrates an example of a manufacturing device according to the invention where the liquid precursor circulates in an accumulator then in a pumping system before being filtered and injected into the crystalline growth cavity, the retentate retained by the filtration being refilled in the accumulator.

FIG. 14 illustrates, in the top view, an example of a substrate comprising a plurality of pixels partly covered with a seed layer with percolating crystalline grains.

### DETAILED DISCLOSURE OF PARTICULAR EMBODIMENTS

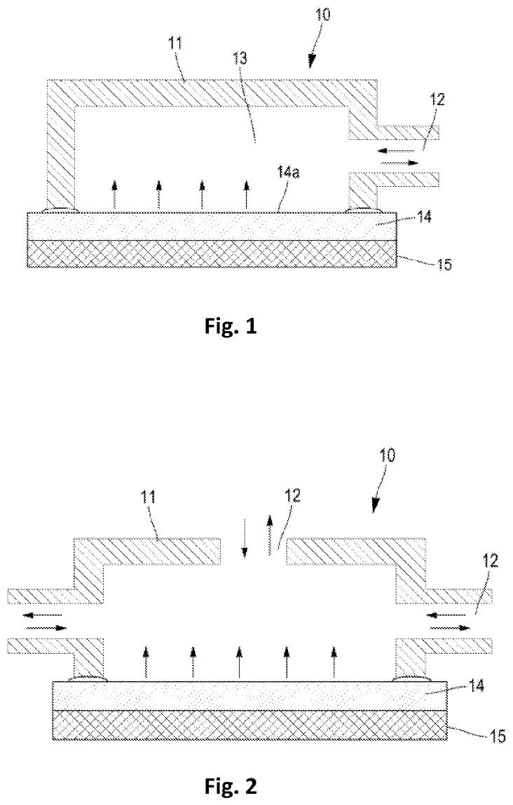

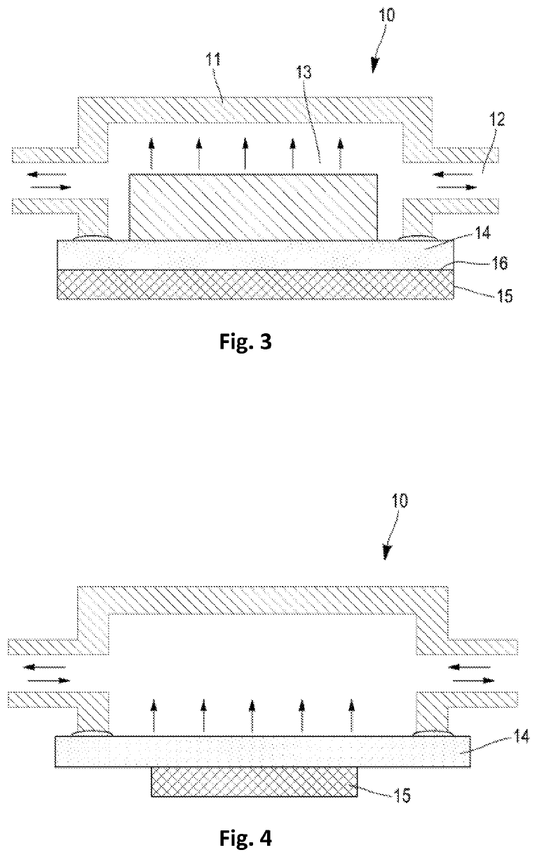

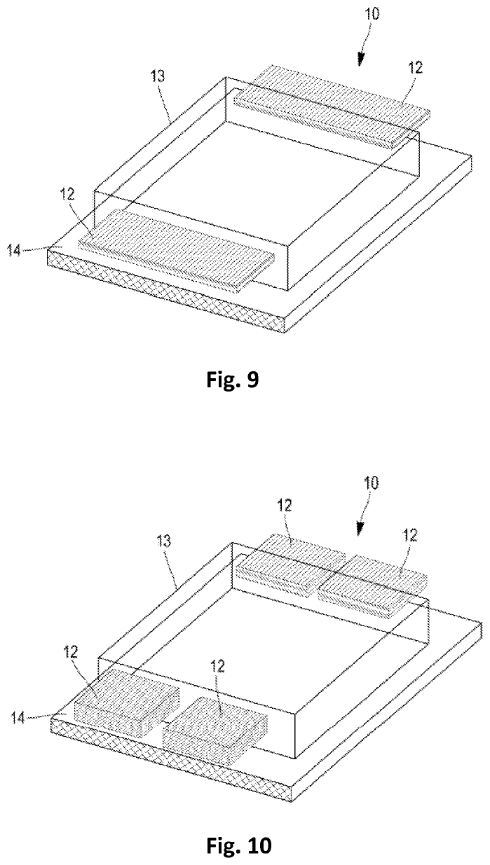

In the appended FIGS. 1 to 14 and in the following description, elements which are functionally identical or similar are identified by the same references.

In addition, the different elements are not represented to scale so as to favor the clarity of the figures for ease of understanding.

Furthermore, the different embodiments or examples and variants are not mutually exclusive and may, on the contrary, be combined with each other.

The invention relates firstly to a manufacturing device 10 allowing manufacturing a crystalline conversion layer by liquid process.

The target fields of application are in particular the manufacture of X or gamma ray detectors for medical radiography, non-destructive testing, security, nuclear, and detection of particles in the large scientific instruments of astronomy and physics. However, these fields are not limiting. For example, the manufacture of scintillators for the conversion of X or gamma photons into visible photons may be considered. Just like the manufacture of detectors in other wavelengths of the electromagnetic radiation such as visible photons with wavelengths comprised between 400 and 800 nanometers or near-infrared with wavelengths greater than 800 nanometers.

By crystalline conversion layer, it should be understood that one or several crystals produce for example an electrical response when photons or charged or uncharged particles pass through them. The crystals composing the conversion layer may also, depending on the application and their physical nature, be selected for their ability to absorb energy radiation such as X, gamma rays or charged or uncharged particles, and convert them into another more easily measurable radiation. The terms “crystalline layer” represent a monocrystalline or polycrystalline layer. A monocrystalline layer thus consists of a single grain with a single crystalline orientation. A polycrystalline layer consists of an assembly of grains with different crystalline orientations.

By the terms “from a growth solution”, which are equivalent to the terms “by liquid process”, it should be understood that the crystalline conversion layer is obtained from one or several dissolved precursor elements (called solute) in one or several solvents, the whole being in liquid form and called growth solution of the crystalline conversion layer in the following text. By varying parameters such as the temperature of the growth solution, it is then possible to promote the growth of the crystalline conversion layer.

In the text, the terms “growth solution” and “liquid precursor” are equivalent.

The principle, for there to be formation of the crystalline conversion layer in solid form, is that the dissolved precursor is configured to be in a supersaturation state, this state being able to be induced by a given temperature. Thus, the solute concentration (which is the precursor of the crystalline conversion layer dissolved in the solution) must be slightly higher, in the range of a few percent, for example 5%, than the solubility limit in the solvent thus forming the growth solution which is in the supersaturated state. In this state, the formation of conversion crystals from the growth solution is thermodynamically favorable.

The configuration of the supersaturation of the solute in the growth solution has as parameters the temperature, the solute concentration of the conversion crystal, the nature of the solvent, the use of a non-solvent or the pressure. The conditions allowing the growth are known to those skilled in the art. In the case of using the temperature as a driving force, it is possible to obtain the crystallization by increasing temperature in the case of retrograde solubility. In this case, the solubility decreases when the temperature increases. In the case of a direct solubility, the crystallization is obtained by decreasing the temperature. Thus, by accurately configuring the temperature profiles in the manufacturing device, it is possible to select where and when the crystallization of the crystalline conversion layer may take place.

Conversely, it may be advantageous to temporarily maintain the solute in a undersaturation state, where the conversion crystal solute concentration is slightly lower, in the range of 1%, than the solubility limit of the conversion crystal solute in the solvent. This state allows partially dissolving the conversion crystals of the crystalline layer which would be already formed or a possible seed layer 17. This partial dissolution allows preferably eliminating certain structural defects. Thus, a crystalline surface with fewer defects and stresses is advantageously obtained before carrying out a subsequent growth phase where the solute (precursor of the crystalline conversion layer) is in a supersaturation state.

The crystalline conversion layer to be manufactured may be a hybrid perovskite combining an organic part and an inorganic part such as CH₃NH₃PbBr₃. It may also be an all-inorganic perovskite such as CsPbBr₃. It advantageously has a general chemical formula ABX₃, including mixed compositions such as A⁽¹⁾_{1-(y2+ . . . +yn)}A⁽²⁾_{y2 . . .} A⁽ⁿ⁾_{yn}B⁽¹⁾_{1-(z2+ . . . +zm)}B⁽²⁾_{z2 . . .} B^{(m)}_{zm}X⁽¹⁾_{3-(x2+ . . . +xp)}X⁽²⁾_{x2 . . .} X^{(p)}ₓₚ where A⁽ⁿ⁾ and B^{(m)} respecting the electronic neutrality rule. A⁽ⁿ⁾ corresponding to organic or inorganic cations, B^{(m)}corresponding to metal ions (example: Pb²⁺, Sn²⁺) and X^{(p)} corresponding to halogen anions (Cl⁻, Br⁻, I⁻) so that the ionic rays involved on each site A, B and X lead to the formation of structures of octahedrons joined by vertices. The indices n, m, and p being integers. The indices x, y and z being the different molar percentages. Some examples of compositions are given below: MAPb₃, MAPbCl₃, MAPbI₃,Brₓ, MAPbBr₃₋ₓClₓ, MA_{y}GA_{1-y}PbI₃, FAPbBr₃, CsPbBr₃, Cs₂AgBiBr₆, CsFAPbI₃, Cs_{y}FA_{1-y}PbI₃₋ₓBrₓ, Cs_{1-y-z}MA_{y}FA_{z}PbI₃₋ₓBrₓ. MA corresponding to methylammonium [CH₃NH₃]⁺, FA corresponding to formamidinium [HC(NH₂)₂]⁺ and GA corresponding to guanidinium [C(NH₂)₃]⁺.

Other perovskite structures are also possible such as A′₂C¹⁺D³⁺X₆, A₂B⁴⁺X₆ or A₃B₂³⁺X₉ with A, A′, C, D and B being cations, B being notably a metal cation, and X being a halogen anion. A, A′, B, C, D, X being a single element or a mixture of at least two elements.

The crystalline conversion layer to be manufactured, the formula of which is explained above, may also be doped with ionic or non-ionic, organic or inorganic additives. The conversion crystal to be manufactured may also be formed according to other compositions similar to perovskites such as according to the terms: vacancy-ordered double perovskite, 2D layered perovskite, perovskite-like materials, defect perovskites, elpasolites, double perovskite. Finally, other types of materials may compose the crystalline conversion layer such as the materials of the Ruddlesden-Popper, Dion-Jacobson, Chalcogenides or else Rudorffites types.

The solvent used may be a mixture of solvents. The solvent is preferably of the polar and aprotic type. It may be for example N,N-dimethylformamide, Dimethyl sulfoxide, gamma-Butyrolactone, acetonitrile, N-methyl-2-pyrrolidone, etc . . .

As illustrated in FIGS. 1 to 6, the manufacturing device 10 comprises a first wall 11 and a substrate 14 defining therebetween a crystalline growth cavity 13. The crystalline growth cavity 13 is supplied with growth solution. This growth solution is introduced and evacuated from the crystalline growth cavity 13.

The substrate 14 may be an inert surface serving only as a support or else be a functionalized surface of an optoelectronic device as illustrated in FIG. 14, a matrix of active or passive pixels of detectors containing transistors.

In an example illustrated in FIGS. 1 to 6, the first wall 11 is sealingly fastened to the substrate 14 so that the growth solution, controlled in supply in the crystalline growth cavity 13 by an inlet/outlet device 12, is extracted from the crystalline growth cavity 13 only by the inlet/outlet device 12 then operating in extraction control or by a spontaneous flow evacuation, for example in the form of an overflow or siphoning orifice, arranged in the first wall 11 or for example in the form of a siphon arranged in a portion of the substrate 14 located at the growth cavity 13 and provided for this purpose. The terms “spontaneous flow” it should be understood a free and natural flow, without any device aimed at modifying the flow. A resulting benefit is a lower implementation cost.

In other words, there must be no unwanted leaks of solution between the first wall 11 of the crystalline growth cavity 13 and the substrate 14, that is to say at the junction between the two.

For example, a joint may be set up between the first wall 11 and the substrate 14. This joint is preferably chemically inert vis-á-vis the solvent used to dissolve the liquid precursor. Its material may, for example, be TEFLON© or even KALREZ©. In another example, it is possible to deposit a glue joint such as silicone or to weld the first wall 11 on the substrate 14 by means of a chemically inert thermoplastic with a low melting point such as polypropylene to make the junction. In this case, the joint must be made and then destroyed at each new growth. In the case where the joint must be destroyed, it may be removed mechanically, chemically, thermally or using light.

In one example, the joint is fastened on the first wall 11 but not on the substrate 14. This allows moving the first wall 11 on the substrate 14 between each growth.

In an example not illustrated, a holding system allows mechanically holding in place at least the first wall 11 and the substrate 14 to prevent the leaks between the first wall 11 and the substrate 14 by maintaining a pressure at the intersection between the first wall 11 and the substrate 14. It may be a flange, a screwing device or even a weight for example.

In the invention, the growth takes place only on one face of the substrate and in the area of interest. There is no crystallization on the rear face or on the edges of the substrate, for example heterogeneous nucleation on the ridges of the substrate, as could be the case in an uncontrolled manner if the substrate were completely immersed.

The first wall 11 may be formed in a material such as glass, a fluoropolymer (PTFE®) or polypropylene.

As illustrated in FIGS. 1 to 6 and 8 to 11, the manufacturing device 10 also comprises at least one inlet/outlet device 12 of the growth solution which controls over time at least one function among the supply or extraction of the growth solution, respectively to and from the crystalline growth cavity 13. By inlet and outlet of the growth solution, it should be understood that the latter is respectively injected which is equivalent to the term “supplied”, or sucked in which corresponds to the term “extracted”, to and from the crystalline growth cavity by an inlet/outlet device 12 carrying out the different functions sequentially or by different inlet/outlet devices 12 each carrying out only one of the functions. Equivalently, the growth solution inlet and outlet flow rate may be modified to adjust the supply of dissolved precursor, that is to say the solute, at the substrate, in the crystalline growth cavity 13 and/or at each of the faces of the crystalline conversion layer during its formation. The same inlet/outlet device 12 may carry out the two injection and suction functions sequentially. In one example, a single inlet/outlet device 12 is arranged in the wall of the crystalline growth cavity 13 to inject the growth solution and a liquid free evacuation, that is to say by a non-controlled spontaneous flow, in other words always open, arranged in the first wall 11 or in the substrate 14, is provided to evacuate the solution from the crystalline growth cavity 13. Preferably, several inlet/outlet devices 12 are formed through the walls of the crystalline growth cavity 13 and each performs only one liquid injection or extraction function. The injection nozzles and the evacuation nozzles thus formed are spatially distributed and may be temporally synchronized so as to promote the circulation of liquid in the crystalline growth cavity 13. In the text, the terms “nozzles” and “inlet/outlet device” are equivalent.

The variation over time consists, for example, in the change from the supply function to the growth solution evacuation or extraction function as the conversion crystal grows, or even in the change in the growth solution flow rate, or else in the change of passing mode (injection, extraction or evacuation) to the blocked state. Preferably, the variation over time consists of opening and closing inlet/outlet devices 12 carrying out only one function among the injection or evacuation or extraction, independently and spatially, depending on the location of the nozzle, and temporally (injection or evacuation or extraction), in order to adequately stir the liquid flow in the cavity. The advantage is to be able to adapt the flow and the spatial arrangement of the liquid precursor according to the progress of the growth of the conversion crystal. Indeed, this growth of the crystalline layer modifies the flow of the growth solution above and around the crystalline conversion layer being formed.

In an example illustrated in FIGS. 2 to 6 and 8 to 11, a plurality of inlet/outlet devices 12 of the growth solution are arranged on either side of the substrate 14, parallel to the forming face 14a. The inlet/outlet devices 12 may be doubled or tripled or consist of a multitude of orifices like a shower. The liquid precursor inlet/outlet devices 12 may be located on all the faces of the reaction cavity 13, and independently of their injecting or extracting character.

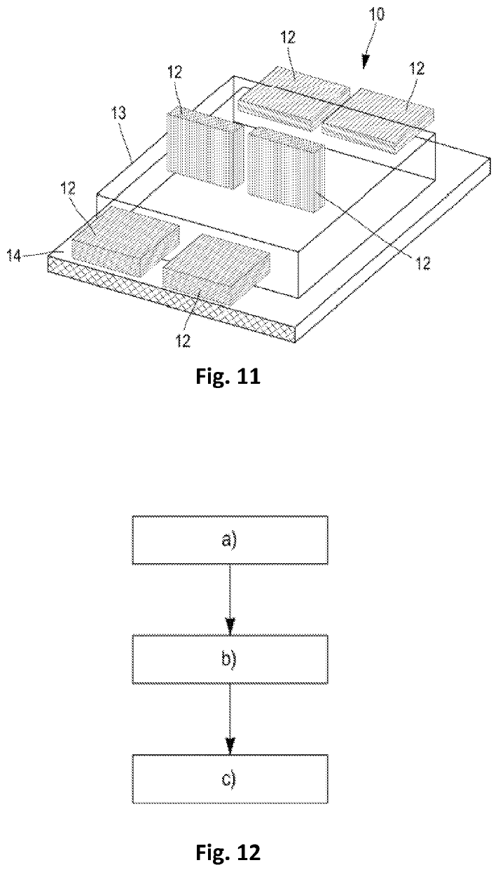

In another example illustrated in FIGS. 2 and 11, at least one inlet/outlet device 12 of the growth solution is arranged facing the forming face 14a. Also in this example, the inlet/outlet devices 12 may be doubled or tripled or consist of a multitude of orifices like a shower. This allows homogenizing the growth. It may thus be considered to inject growth solution via inlet/outlet devices 12 arranged laterally through the first wall 11 of the crystalline growth cavity and evacuate the growth solution by an inlet/outlet device 12 arranged facing the forming face 14a.

Thus, notably depending on the arrangement of the inlet/outlet devices 12 in the manufacturing device 10, the flow rate or even the pressure, the growth solution enters and leaves the crystalline growth cavity, so that this circulation maintains preferably a homogeneous concentration of dissolved precursor of the conversion crystal over the entire growth front, that is to say at the surface of the crystalline conversion layer being formed-solution interface. This is particularly advantageous for large surfaces greater than 20 cm² and allows obtaining crystalline conversion layers having a distribution as homogeneous as possible of the grain boundaries and good homogeneity at the thickness of the grains.

It is possible to carry out the growth of the crystalline conversion layer with the liquid precursor under pressure so as on the one hand to have a parameter other than the temperature likely to affect the solubility, and on the other hand to promote the circulation of the growth solution in the crystalline growth cavity 13. Thus, this would allow avoiding possible solute (precursors) supply problems at the crystalline layer-growth solution (growth front) interface which may generate growth instabilities.

The growth of the crystalline conversion layer may be stopped or reduced by the variation in flow rate of the growth solution and/or by a change in temperature.

Preferably, the inlet/outlet device(s) 12 are arranged and driven so that the liquid precursor may circulate on the growth front which is the surface of the crystalline conversion thick layer parallel to the plane of the substrate, throughout the growth of the crystalline conversion thick layer. Thus the liquid precursor circulates on the surface of the crystalline conversion layer over a surface equivalent to the target detection area. Indeed, the growth is advantageously carried out, through the object of the invention, in situ directly in the radiation detection or conversion device. This is advantageous compared to devices that mechanically constrain the growth between two plates. Indeed, in these devices, the solution cannot circulate on the surface of the crystalline conversion layer covering the detection area, but may only circulate at the lateral growth fronts of the crystalline layer.

The inlet/outlet device 12 may for example be constituted by solution inlet and outlet nozzles positioned so as to guarantee a sufficient and homogeneous flow of growth solution over the entire growth surface of the crystalline conversion layer. Such an arrangement allows minimizing the dead areas, without renewal of fluid unlike systems designed for the growth between plates for example.

It may also be considered that several growth solutions or solutes, that is to say the dissolved precursors, of different nature may be introduced by different inlet/outlet devices 12 at the same time or sequentially, or by the same inlet/outlet device 12 sequentially.

In other words, it is possible that the introduction, into the crystalline growth cavity 13, of two different liquid precursors, that is to say growth solutions of different nature, may be done one after the other without purging between the two. In another example, it is possible to first inject a first liquid growth solution alone, then the first growth solution and a second liquid growth solution of different nature are injected at the same time by different inlet/outlet devices 12 or by the same inlet/outlet device 12, then the second growth solution is injected alone. A first crystalline conversion layer of a first nature would be deposited up to a certain thickness then, the solution supply line purged by an inert gas for example. Then, by changing the nature of the precursor/growth solution, a second crystalline conversion layer of a second nature would be obtained above. This example would allow depositing several compounds on top of each other provided that the respective crystalline lattice parameters allow it. If the line is purged with a neutral gas (Ar, N₂) between each composition, the transition from one crystal to another would not be polluted by a possible contact with the ambient air. In the case of perovskites, it would be possible to deposit, for example and in an order to be defined by those skilled in the art, multilayers based on MAPbI₃, MAPbBr₃, MAPbCl₃or any other perovskite composition such as solid solutions. This multilayer configuration would be advantageous for modifying the interface at the contacts of possible electrodes contained on the substrate 14 at the location of the substrate where the growth is considered by locally modifying at the interfaces the valence and conduction band levels and thus the energy barriers to the injection of electrical charges. This also allows passivating the surface of the obtained conversion crystal thick layer by crystallizing a less environmentally sensitive perovskite structure such as for example a perovskite of the Phenethylammonium or Buthylammonium halogeno-plombate BA₂PbX₄ type. The layer in contact with the substrate could also have mechanical properties adapted to minimize the mechanical stresses due to the temperature-related expansion differences, between the substrate 14 and an obtained perovskite thick layer.

In one example, the growth solution does not completely fill the crystalline growth cavity 13. The height of the growth solution may also be adjusted. This can allow regulating or even stop the growth of the crystalline conversion layer if necessary.

In another example, the inlet/outlet device 12 also allows injecting an inert gas (argon, nitrogen) for example, into the growth solution at the crystalline growth cavity 13 or in advance to the supply of the growth solution into the crystalline growth cavity 13. This allows degassing and purging the supply line of the inlet/outlet devices 12 and of a possible accumulator 70 of the manufacturing device, all with a neutral gas before carrying out the growth of the crystalline conversion layer. This allows controlling the conditions such as the humidity, oxygen or even ozone level.

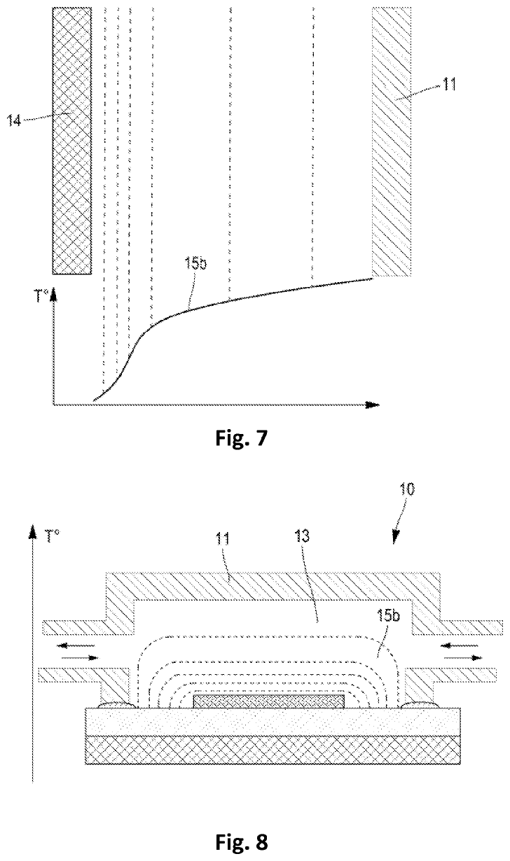

The manufacturing device 10 further comprises a temperature setting device 15 to create a temperature profile 15b at least in the crystalline growth cavity 13 and/or the substrate 14 and/or the first wall 11. An example of a temperature profile 15b is schematically represented in FIGS. 7 and 8. The temperature profile 15b may consist of a temperature gradient arranged between the substrate 14 and the first wall 11 or even between the crystalline conversion layer being formed and the first wall 11. The temperature profile may be variable and adjusted over time. For example, it may be adapted as the growth of the crystalline conversion layer progresses either in a predetermined manner or by continuous monitoring of thickness. Thus, the growth may be controlled in real time using camera tracking allowing continuous measurement of the thickness of the growing layer or with the Fizeau interferometric method. In this configuration, a feedback loop on the temperatures of the local areas may be set up so as to control the homogeneity of growth over the entire desired surface and over time.

The temperature profile 15b controls the free formation of the crystalline conversion layer over a thickness greater than 1 micrometer, from all or part of a forming face 14a of the substrate 14 facing the interior of the crystalline growth cavity 13, in a direction preferably transverse to said forming face 14a.

In an advantageous example, the growth temperature is lower than 80° C. so as to minimize the differential thermal expansions between the substrate and the thick layer of the conversion crystal.

In the text, a free formation is equivalent to a formation without limitations or external physical stresses facing each other. The free formation is for example distinct from a crystal formation obtained between two plates facing each other and distant from a small space in which the growth would be confined and guided parallel to the two plates. Such limitations may lead to mechanical stresses due to the confinement of the crystalline layer between the two plates during temperature variations which is detrimental to the crystalline quality. Thus, a free formation is different from a formation, of a crystal or a polycrystal, mechanically constrained between two walls and allowing only one growth direction or certain possible growth directions. In other words, a free formation is obtained when the crystalline conversion layer grows from a substrate but without encountering a wall, arranged facing the substrate, constraining its growth at least in thickness.

In the present invention, the entire thickness of the crystalline conversion layer is obtained by the free formation of the crystalline conversion layer. This advantageously allows obtaining a growth of the crystalline layer transversely to the substrate and not parallel to the substrate. This arrangement is also advantageous to obtain a crystalline layer in situ directly and transversely at given location(s) of the substrate.

The term “formation” is equivalent to a growth, an homoepitaxy, an heteroepitaxy or even a crystallization leading to the formation of a polycrystalline layer.

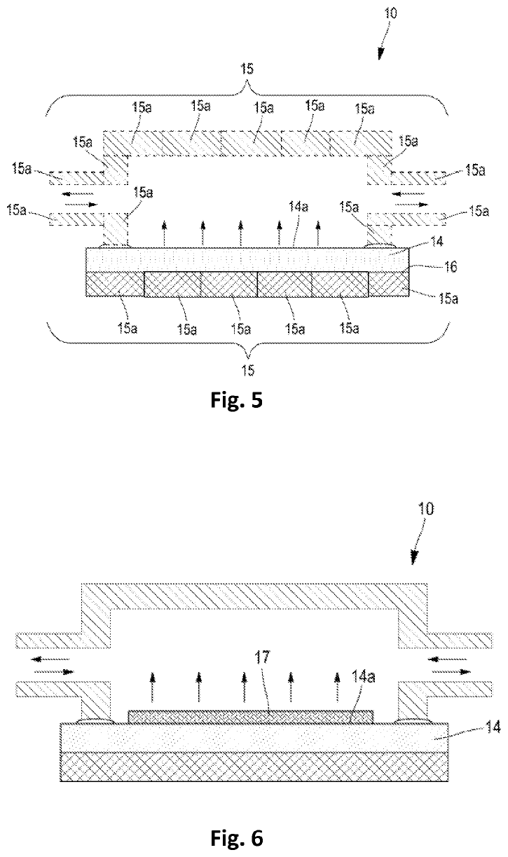

In an example illustrated in FIG. 5, the temperature setting device 15 allows setting with high accuracy; 0.1° C. and preferably 0.01° C.; the temperature under the substrate and/or in the first wall and/or in the inlet/outlet devices 12 as well as possibly in the growth solution inlets to which they are connected. As illustrated in FIGS. 7 and 8, this arrangement allows regulating the temperature of the growth solution before entering the crystalline growth cavity 13 as well as configuring the thermal geometry of the growth area. It allows maintaining the growth, over time, by setting the temperature of the growth solution in the crystalline growth cavity 13 for example by maintaining the temperature above the saturation equilibrium, in the case of retrograde solubility, or a temperature lower than the saturation temperature, in the case of direct solubility. Thus, the temperature profile 15b created by the temperature setting device 15 can comprise, in the case of direct solubility, at least one temperature lower than a temperature of the substrate 14. In one example, it also allows establishing, in the crystalline growth cavity 13, a temperature gradient normal to the substrate. The temperature profile, generating a supersaturation profile of the solution, can also be time and/or space-modulated to adapt to the progress of the growth of the crystalline conversion layer. Thus, the supersaturation profile can be moved in the crystalline growth cavity 13 as the crystalline conversion layer grows. The time modulation of the temperature gradient allows maintaining the normal growth on the substrate, the duration of the growth allows setting the thickness of the crystalline layer. This thickness can also be set by the position of the saturation limit set in the cavity by the thermal gradient. The crystalline conversion layer, once formed, preferably has a thickness greater than 1 micrometer, preferably greater than 100 micrometers and even more preferably greater than 300 micrometers. In the case of direct conversion X-ray detectors, the thickness of the conversion crystal to be manufactured can be defined so as to absorb more than 85% of the incident radiation at the target energy for the application. For example, to absorb X-rays equivalently to 600 micrometers of CsI (85% of X-ray absorption at RQAS and 50% at RQA9), a crystalline conversion layer having a thickness of 600 micrometers of CH₃NH₃PbI₃ or 1300 micrometers of CH₃NH₃PbBr₃ at RQA9 (X-ray spectrum centered on 50 keV according to the standard IEC62220-1), and a thickness of 450 micrometers of CH₃NH₃Pb₁₃ or 800 micrometers of CH₃NH₃PbBr₃ at RQA9 (X-ray spectrum centered on 70 keV according to the standard IEC62220-1) should be formed.

The temperature profile can also be adapted, as in FIG. 8, to limit the possibility of growth of the crystalline conversion layer on the sides of the crystalline conversion layer. The temperature profile can thus be arranged so that the solution is in a supersaturation state only in a direction transverse to the substrate 14 but not on the sides of the crystalline conversion layer. This is advantageous to obtain a crystalline conversion layer with a thickness of several micrometers, and preferably several hundred micrometers, while maintaining the crystalline conversion layer according to an imprint provided at a specific location of the substrate 14. Thus, in an example illustrated in FIG. 3, the temperature setting device 15 is configured to obtain the formation of the crystalline conversion layer only on a limited part of the forming face 14a of the substrate 14 without contact with the first wall 11, the remaining part of the forming face 14a remaining devoid of conversion crystal. An aspect ratio of up to 1 to 1400 between the thickness of the conversion crystal and its extent on the substrate can thus be advantageously obtained. In one example, the obtained crystalline layer can reach a thickness of 300 microns for a lateral dimension of 40 centimeters. It would not be easy to obtain such an aspect ratio, with a technique that does not comprise means for generating a temperature profile allowing guiding the growth of the crystalline conversion layer according to a particular configuration.

In an example illustrated in FIG. 5, all or part of the temperature setting device 15 is arranged in at least the first wall 11 and/or the conversion crystal liquid precursor inlet/outlet device 12 and/or a second wall 16 formed at an outer face of the substrate 14 opposite the forming face 14a. This arrangement advantageously allows accurately adjusting the temperature profile in time and in space. Thus, the growth solution can be temperature-adjusted in a differentiated manner between its interface with the crystalline layer being formed and its interface with the first wall 11 to promote the growth only at the crystalline conversion layer. It is also possible to configure, and modify in time and space, the temperature profile to favor the growth of the crystalline conversion layer in the direction of the thickness.

The temperature setting device 15 comprises, in a complementary example, a plurality of control areas 15a, each control area 15a having an area temperature that can be modified by the temperature setting device 15, independently from one control area 15a to another control area 15a. This arrangement advantageously allows accurately adjusting the temperature profile in time and in space. These control areas 15a can be disposed in all directions of space.

In one example, the temperature setting device 15 is equipped with a Peltier type module allowing obtaining temperatures lower than those of the liquid precursor or cooling the latter.

During crystallization, the supersaturation of the growth solution can be maintained by varying its temperature over time. Advantageously, the growth/crystallization of the layer can take place at constant temperature and at constant concentration. In this case, it is necessary to compensate for the drop in solute/precursor concentration related to the growth of the layer during passage into the growth cavity. Indeed, the dissolved precursor concentration decreases because a part crystallizes on the surface of the layer.

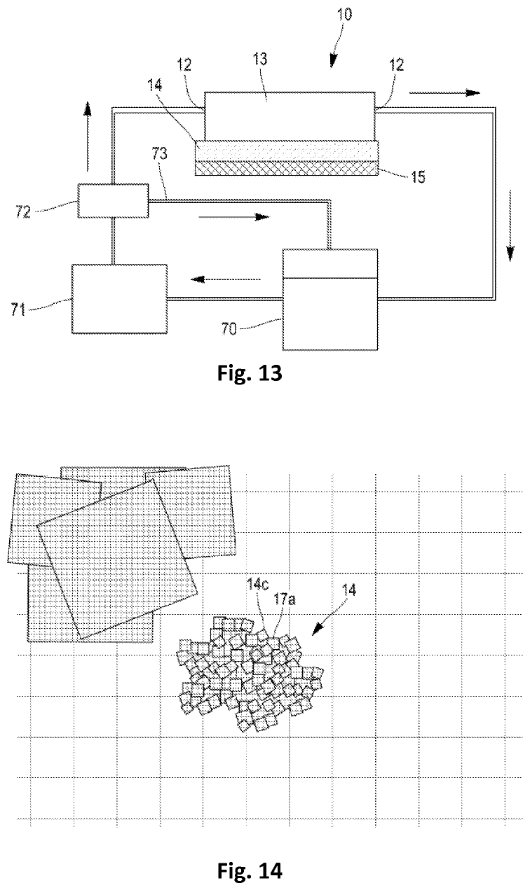

Thus, in an example illustrated in FIG. 13, the growth solution can be obtained by dissolving a feeder body, formed for example of an excess solid perovskite, in a reaction chamber attached to the crystalline growth cavity, which can be an accumulator 70. A constant temperature difference must then be maintained between the accumulator 70 and the crystalline growth cavity 13. The growth solution is sucked in by a pumping system 71 then filtered 72 before being fed into the crystalline growth cavity 13. Then the growth solution flows back by circulation to the accumulator 70 or it is again enriched in precursor/solute and so on in a closed circuit. The retentate 73 (which is retained by the filter) is reintroduced into the accumulator 70. This configuration of the manufacturing device 10 allows 100% of the feeder body dissolved in the accumulator 70 to be deposited on the substrate in the form of conversion crystals, which implies a gain in manufacturing cost as well as a better control of the first instants of the crystallization of the crystalline conversion layer. The manufacturing device being in a closed circuit, it makes it easy to control the atmosphere for example the humidity, oxygen or even ozone levels.

It may also be advantageous to raise or lower the temperature of the liquid precursor before it is injected into the reaction cavity 13 in order to accelerate the growth for example.

The growth on the substrate 14 can be carried out without specific treatment of the substrate, and spontaneously initiated by the temperature difference on the substrate. It can also advantageously be initiated from a previously formed seed layer 17.

In an example illustrated in FIG. 6, all or part of the forming face 14a thus comprises a conversion crystal seed layer 17. This seed layer allows initiating the growth of the crystalline conversion layer by homoepitaxy or heteroepitaxy which limits the spontaneous growth on unwanted surfaces. This seed layer is of the same nature as or of a different nature from the crystalline conversion layer.

In the case where a seed layer is used, the grains constituting it must be oriented so as to promote the growth along the desired crystalline axis in the axis normal to the plane of the substrate. For example, for MAPbBr3, if the person skilled in the art wishes that the axis to be grown perpendicular to the substrate be the orientation {100}, the grains of the seed layer in this axis should oriented as well as possible, that is to say according to a main crystalline orientation. By at best, it should be understood that, based on a θ/2θ X-ray diffractogram, the ratio of peak areas {nn0}/{n00} and {nnn}/{n00} with n=1, 2, 3, 4, is less than 2%, preferably less than 0.5%, and even more preferably less than 0.1%. The seed layer can be continuous or discontinuous, that is to say be composed of percolating or non-percolating crystalline grains (17a). The main axis to be grown may be different such as for example {110} or {111}, but the ratios to respect remain the same. By main crystalline orientation, it should be equivalently understood “preferred orientation”.

The invention advantageously allows controlling the conditions conducive to the growth of the crystalline conversion layer notably by adapting the thermal geometry and renewing the solution in the cavity. The manufacturing device as described advantageously allows obtaining a homogeneous growth of all the grains of the seed layer 17. By homogeneous it should be understood that all the grains, whatever their positions on the substrate, have the same advance speed of the growth faces. Thus, if the orientation of the grains forming the seed layer is controlled so that they all have the same crystallographic direction perpendicular to the substrate (global symmetry Cₙ n=1, 2, 3, . . . , ∞), then the number of grains in the final crystalline conversion thick layer is equal to the number of grains of the seed layer. All the grains growing at the same speed and in the same direction, none takes the lead over its neighbors. This has two main advantages: the entire growth front of the layer is planar and the grain boundaries are vertical and equal in number to those of the seed layer. The thickness homogeneity of the crystalline conversion layer thus favorably contributes to the homogeneity of the photoelectric conversion efficiency of the detectors. Thus, it is possible to control the number of grains in the thick layer, by correctly mastering those present in the nucleation layer. In particular, the grains can have lateral dimensions ranging from a few microns to several hundred microns. They can be percolating or disjointed. The important parameter is the grain density per unit area. In the thick crystalline conversion layer, the grain boundaries are areas which behave differently from the remainder of the layer from an electronic point of view notably by the presence of structural defects which generate electronic traps or ionic migration areas. In the case where the crystalline conversion layer is made on a detector formed of pixels 14c for example, if these areas corresponding to the grain boundaries cross several pixels 14c, these pixels 14c may behave differently from the others, and the presence of the grain boundaries may become visible in the X-ray radiography image for example. In this sense, it would be favorable for the crystalline layer to include several grains per pixels 14c so as to homogenize the performances of pixels 14c to pixels 14c and not to see the trace of grain boundaries on the images. In other words, this amounts to averaging on each pixel the electronic disturbances related to the grain boundaries. The pixels 14c can have lateral dimensions from a few microns to several hundred microns. These dimensions are typically 80 microns to 200 microns for medical applications. It is advantageous to have at least one grain per pixel on the face of the thick layer in contact with the pixel, preferably 2 or 3 grains which belong to at least one pixel which corresponds to a density greater than 80 grains/mm² for a square pixel with a side of 150 micrometers. An even more preferred density is greater than 5 grains belonging to one pixel which corresponds to a density greater than 200 grains /mm² for a square pixel with a side of 150 micrometers. The control of the grain density per pixel can be carried out by mastering the conditions of deposition of the nucleation layer, for example the layer drying speed.

The invention advantageously allows carrying out the crystallization of the crystalline conversion layer with a volume of liquid precursor in contact with the substrate lower than in the conventional case where the substrate is immersed in a solution. This gain is even more marked in the case of the embodiment presented in FIG. 13 where several layers can be successively developed with the same solution without compromising its purity, unlike the case where the substrates would be immersed. This represents significant gains in development time and production cost.

In one example, it is possible to thermally annealing the substrate 14 in the crystalline growth cavity 13 under a controlled atmosphere or under vacuum before bringing it into contact with the liquid precursor. This allows eliminating the water molecules adsorbed on the surface of the substrate 14.

An optoelectronic device, not illustrated, can be manufactured from the crystalline conversion layer obtained with the manufacturing device 10 of the invention. In order to manufacture this optoelectronic device, an upper electrode is deposited. Preferably, the electrode is continuously deposited over at least the entire surface of the active matrix covered by the crystalline conversion layer. In one example, a single upper electrode is common to all the pixels of the matrix. This electrode can have the same nature as the lower electrode constituting the substrate part on which the crystalline conversion layer is obtained or can be of a different nature as for a photodiode device. It is possible to use metals (Au, Cr, Pt, Pd, Ag), conductive oxides (ITO, AZO, GZO), conductive organic materials (PEDOT-PSS, PANI, graphene, carbon ink) or a superposition of these materials. It is also possible to use one or several interface layers on the electrode to set the work function and the chemical compatibility with perovskite (PEIE, C60, MoO₃, V₂O₅, BCP, SPIRO). The upper electrode is then electrically connected to the external circuit for example via a conductive wire or a conductive line made by printing.

The crystalline conversion layer can finally be encapsulated in air, or under an inert atmosphere (N₂, Ar), or under an anhydrous atmosphere. This can be carried out using a glass cover bonded to a surface of the substrate, which is not covered by the crystalline conversion layer, using a bead of glue, or using an adhesive such as a glue or a pressure-sensitive adhesive and a plastic film including barrier layers. The encapsulation is transparent or opaque to visible light but lets the radiation to be detected pass.

The contact pads of the matrix of pixels are then connected to a readout electronics using hoses and ACF for Anisotropic Conductive Film type adhesives. The matrix can be characterized with the usual readout methods of pixelated imagers.

The invention also relates to a method for manufacturing a crystalline conversion layer from a growth solution, in other words by liquid process, on the substrate 14. The method is implemented in a manufacturing device 10 such as that of the examples given above.

As illustrated in FIG. 12, the method comprises the following steps:
a) control, depending on the time and the position of the nozzles, of the supply and extraction of the growth solution by the inlet/outlet device 12 of the manufacturing device 10 to and from the reactor/growth cavity 13 defined between the first wall 11 of the manufacturing device 10 and the substrate 14;
b) creation of a temperature profile 15b by the temperature setting device 15 in at least the crystalline growth cavity 13 and/or the substrate 14, and/or the first wall 11;
c) configuration of the temperature profile 15b to control a free formation of a crystalline conversion layer in a thickness greater than 1 micrometer, from all or part of the forming face 14a of the substrate 14 facing the interior of the crystalline growth cavity 13, in a direction preferably transverse to said forming face 14a.

This method advantageously allows controlling the formation of the crystalline conversion layer with a homogeneous distribution of the grain boundaries and so that they reach a thickness greater than 1 micrometer and more preferably greater than 100 micrometers as detailed in the preceding paragraphs. The method of the invention also allows orienting the growth of the crystalline conversion layer transversely with respect to the substrate 14 from a defined surface of the substrate 14. The crystalline conversion layer thus grows preferably, that is to say mainly, in a single direction transverse to the substrate 14. By the term “mainly”, it should be understood, equivalently manner, that more than 80% of the crystallized mass is formed by growth in the transverse direction, and preferably more than 95%. Parasitic crystals can indeed erratically grow on the edges of the substrate in an unwanted manner. The method of the invention thus differs from growth methods carrying out a growth constrained between two close surfaces. Indeed, to cover surfaces of more than a few square centimeters, these methods carry out a growth mainly in a direction parallel to the two surfaces and not a growth mainly in a direction transverse to the substrate, the growth in a direction transverse to the two surfaces being in this case impossible because it is blocked by the two surfaces.

In one example, in step c), the configuration of the temperature profile 15b is modified over time. This allows adapting for example the conditions of saturation of the liquid precursor as the crystalline conversion layer becomes thicker.

In an additional example, in step c), the temperature profile 15b is formed in at least the crystalline growth cavity 13 and/or the substrate 14 and/or the first wall 11. This arrangement allows notably finely controlling the temperature profile managing the growth of the crystalline conversion layer. Indeed, the growth depends, by the supersaturation of the growth solution, on the local values of the temperature at the crystalline layer-solution interface.

In an additional implementation, in step c), the temperature profile 15b is configured to obtain the formation of the crystalline conversion layer only on a limited part of the forming face 14a of the substrate 14 without contact with the first wall 11, the remaining part of the forming face 14a being devoid of conversion crystal. This configuration allows limiting the generation of parasitic crystals creating short-circuits. It also allows favoring the growth of the crystalline conversion layer according to only its thickness.

In an additional implementation, in step a), several growth solutions of different nature are fed into the crystalline growth cavity 13 by the inlet/outlet device 12 sequentially.

In one implementation, the manufacturing device 10 comprises a plurality of inlet/outlet devices 12 and wherein, in step a), several growth solutions of different nature are fed, into the crystalline growth cavity 13, each by a different one of the inlet/outlet devices 12, at the same time or sequentially.

These implementations advantageously allow modifying the interface at the contacts of possible electrodes contained on the substrate 14 at the location of the substrate where the growth is considered by locally modifying at the interfaces the valence and conduction band levels and thus the energy barriers to the injection of electrical charges. This also allows passivating the surface of the obtained conversion crystal thick layer by crystallizing a less environmentally sensitive perovskite structure.

The layer in contact with the substrate could also have mechanical properties adapted to minimize the mechanical stresses due to the temperature-related expansion differences, between the substrate 14 and an obtained perovskite thick layer.

The temperature setting device 15 mentioned above, in particular as part of the manufacturing device 10, is according to another formulation configured to create the temperature profile 15b. To this end, the temperature setting device 15 may include several thermally controllable elements in order to create the temperature profile 15b and therefore to obtain, if necessary, the desired thermal geometry of the growth area.

For example, each thermally controllable element can be selected from among a heating element, a cooling element, and an element configured to notably selectively heat or cool. The heating element can be resistive to allow obtaining temperatures strictly higher than the ambient temperature, this ambient temperature being for example comprised between 20° C. and 120° C. The cooling element can be a thermoelectric element such as a Peltier type module. The element configured to heat or cool can be a thermoelectric element such as a Peltier type module which can optionally operate in heating mode or in cooling mode: its operating mode can therefore be adapted. The presence of thermally controllable elements as described allows creating both homogeneous temperature areas (sets of thermally controllable elements allowing heating or allowing cooling) and marked temperature gradients (by combining the use of thermally controllable elements that heat with other thermally controllable elements that cool). Thus, several thermally controllable elements as described above placed under the substrate 14 opposite the crystalline growth cavity 13 can define an area where the temperature is homogeneous laterally to the normal to the plane of the substrate 14 (that is to say the temperature is homogeneous in said area and in a plane parallel to the plane of the substrate 14) for the creation of photoelectric crystals and therefore of the crystalline conversion layer in the growth area.

Consequently, the thermally controllable elements can be distributed so as to delimit the control areas 15a mentioned above.

Operating setpoints for thermally controllable elements can be adjusted by measuring the temperature profile obtained at the surface of the substrate 14. For example, the temperature profile obtained at the surface of the substrate 14 can be measured without contact by infrared thermometry or using a thermocouple.

To limit the crystallization area (that is to say the growth area), the thermally controllable elements can be distributed so as to form a first set of thermally controllable elements and a second set of thermally controllable elements; the thermally controllable elements of the second set of thermally controllable elements adjoining the thermally controllable elements of the first set of thermally controllable elements. The thermally controllable elements of the second set of thermally controllable elements thus allow creating a lateral temperature gradient due to the application of an operating setpoint to the thermally controllable elements of the second set of thermally controllable elements that is significantly different from an operating setpoint of the thermally controllable elements of the first set of thermally controllable elements. By “significantly different” speaking of two temperature setpoints, it should be understood that the difference between these two temperature setpoints can be comprised between a few degrees and a few tens of degrees. By “lateral temperature gradient”, it should be understood that this gradient is established in a plane parallel to the plane of the substrate 14. Again, the measurement of the temperature profile at the surface of the substrate 14 allows adjusting, by trying to obtain the most marked possible lateral temperature gradient, the operating setpoints of the thermally controllable elements of the first set of thermally controllable elements which allow the crystallization and the operating setpoints of the thermally controllable elements of the second set of thermally controllable elements which tend to prevent the crystallization.

Similarly, a thermal geometry favorable to the desired growth can be made in a direction perpendicular to the substrate plane (that is to say in a measurement direction of the thickness of the substrate 14) using thermally controllable elements arranged inside a cell and/or on the periphery, on the top and on the bottom of the cell. The cell includes the first wall 11 and the substrate 14 defining therebetween the crystalline growth cavity 13. These thermally controllable elements combined with the thermal conductivity of the cell allow obtaining different temperatures between the substrate 14 and the top of the cell so as to confine the crystallization in a given volume above the substrate 14. In the present paragraph, the concepts of top and bottom are given according to an axis providing the height while moving away from the substrate 14 towards the wall 11 which ends up above the substrate 14. This volume and more particularly the thickness over which the crystallization is possible are then:
controlled by setpoint temperature(s) set for the thermally controllable elements; and
dependent on the thermal conductivity of the cell.
   The temperature profile thus desired perpendicular to the plane of the substrate 14 can be obtained by adjusting the setpoints of the different thermally controllable elements, the obtained profile being controlled by local measurements of temperatures by means of thermocouples. The presence of one or several thermally controllable elements in the cell allows heating the growth solution and obtaining a circulation of a heating growth solution.

The first wall 11 can also be made of a metallic material (such as for example aluminum or copper) if necessary covered with a chemically inert liner or made of plastic material (such as for example polytetrafluoroethylene).

The substrate 14 can be made of glass or plastic such as for example a polyimide.

1. A manufacturing device allowing manufacturing a crystalline conversion layer from a crystalline conversion layer growth solution, the manufacturing device comprising:
a first wall and a substrate defining therebetween a crystalline growth cavity;
at least one inlet/outlet device of the growth solution controlling, over time, at least one function selected from the group comprising the supply and extraction of the growth solution respectively to and from the crystalline growth cavity;
a temperature setting device creating a temperature profile in at least one element selected from the group comprising the crystalline growth cavity, the substrate and the first wall;
the temperature profile controlling a free formation of the crystalline conversion layer over a thickness greater than 1 micrometer, from all or part of a forming face of the substrate facing the interior of the crystalline growth cavity, in a direction mainly transverse to said forming face;
the entire thickness of the crystalline conversion layer being obtained by the free formation of the crystalline conversion layer.

2. The manufacturing device according to claim 1, wherein the first wall is sealingly fastened to the substrate so that the growth solution, introduced into the crystalline growth cavity by said at least one inlet/outlet device, is extracted from the crystalline growth cavity only by at least one element selected from the group comprising said at least one inlet/outlet device and a spontaneous flow evacuation arranged in the first wall or in a portion of the substrate located at the growth cavity.

3. The manufacturing device according to claim 1, wherein the temperature setting device comprises elements allowing modifying the temperature profile over time.

4. The manufacturing device according to claim 1, wherein the temperature setting device comprises elements allowing configuring the temperature profile at least one element selected from the group comprising the crystalline growth cavity, the substrate and the first wall.

5. The manufacturing device according to claim 1, wherein the temperature profile created by the temperature setting device comprises at least one temperature lower than a temperature of the substrate.

6. The manufacturing device according to claim 1, wherein the temperature profile created by the temperature setting device comprises at least one temperature higher than a temperature of the substrate.

7. The manufacturing device according to claim 1, wherein all or part of the temperature setting device is arranged in at least one element selected from the group comprising the first wall, the conversion crystal liquid precursor inlet/outlet device and a second wall formed at an outer face of the substrate opposite the forming face.

8. The manufacturing device according to claim 1, wherein the temperature setting device comprises a plurality of control areas, each control area having an area temperature that can be modified by the temperature setting device, independently from one control area to another control area.

9. The manufacturing device according to claim 1, comprising a plurality of separate inlet/outlet devices of the conversion crystal growth solution arranged on either side of the substrate, parallel to the forming face.

10. The manufacturing device according to any one of claim 1, wherein at least one conversion crystal liquid precursor inlet/outlet device is arranged facing the forming face.

11. The manufacturing device according to claim 1, wherein all or part of the forming face comprises a seed layer of the conversion crystal.

12. The manufacturing device according to claim 11, wherein at least one part of the substrate is formed of at least one pixel, wherein the seed layer comprises a plurality of percolating or non-percolating crystalline grains, and wherein, at said at least one pixel, the seed layer includes at least one crystalline grain of the plurality of crystalline grains.

13. The manufacturing device according to claim 11, wherein the seed layer offers a main crystallographic orientation along an axis {n00} n being an integer comprised between 1 and 4 inclusive.

14. The manufacturing device according to claim 11, wherein the seed layer offers a main crystallographic orientation along an axis of the group comprising an axis {110} and an axis {111}.

15. The manufacturing device according to claim 1, wherein the temperature profile created by the temperature setting device is configured to obtain the formation of the crystalline conversion layer only on a limited part of the forming face of the substrate without contact with the first wall, the remaining part of the forming face remaining devoid of conversion crystal.

16. The manufacturing device according to claim 1, wherein at least one inlet/outlet device of the growth solution passes through at least one element selected from the group comprising the first wall and the substrate.

17. The manufacturing device according to claim 1, wherein the crystalline conversion layer to be formed is a perovskite of a type from the group comprising ABX₃, A′₂C¹⁺D³⁺X₆, A₂B⁴⁺X₆ or A₃B₂³⁺X₉; A, A′, C, D and B being cations and X being a halogen anion.

18. The manufacturing device according to claim 1, wherein the crystalline conversion layer to be formed is an organic-inorganic hybrid perovskite of formula respecting the electronic neutrality A⁽¹⁾_{1-(y2+ . . . +yn)}A⁽²⁾_{y2 . . .} A⁽ⁿ⁾_{yn}B⁽¹⁾_{1-(z2+ . . . +zm)}B⁽²⁾_{z2 . . .} B^{(m)}_{zm}X⁽¹⁾_{3-(x2+ . . . +xp)}X⁽²⁾_{x2 . . .} X^{(p)}ₓₚ where A⁽ⁿ⁾ and B^{(m)} correspond to cations and X⁽ⁿ⁾ corresponds to a halogen anion.

19. (canceled)

20. A method for manufacturing a crystalline conversion layer from a crystalline conversion layer growth solution on a substrate, the method being implemented in a manufacturing device according to claim 1, the method comprising the following steps:
a) time-dependent control of at least one function selected from the group comprising the supply and extraction of the growth solution from an inlet/outlet device of a growth solution of the manufacturing device to and from a crystalline growth cavity defined between a first wall of the manufacturing device and the substrate;
b) creation of a temperature profile by a temperature setting device in at least one element selected from the group comprising the crystalline growth cavity, the substrate, and the first wall;
c) configuration of the temperature profile to control a free formation of the crystalline conversion layer in a thickness greater than 1 micrometer, from all or part of a forming face of the substrate facing the interior of the crystalline growth cavity, in a direction mainly transverse to said forming face, the entire thickness of the crystalline conversion layer being obtained by the free formation of the crystalline conversion layer.

21. The manufacturing method according to claim 20, wherein, in step c), the configuration of the temperature profile is modified over time.

22.-25. (canceled)
